(19) United States
(12) Patent Application Publication
(10) Pub. No.: US 2024/0387438 A1
(43) Pub. Date: Nov. 21, 2024

(54) CERAMIC SUBSTRATE FOR POWER MODULE, METHOD FOR MANUFACTURING SAME, AND POWER MODULE HAVING SAME

(71) Applicant: AMOSENSE CO., LTD., Cheonan-si, Chungcheongnam-do (KR)

(72) Inventor: Jihyung LEE, Cheonan-si (KR)

(73) Assignee: AMOSENSE CO., LTD., Cheonan-si, Chungcheongnam-do (KR)

(21) Appl. No.: 18/688,448

(22) PCT Filed: Aug. 22, 2022
(86) PCT No.: PCT/KR2022/012479

§ 371 Date: Mar. 1, 2024

(30) Foreign Application Priority Data
Sep. 3, 2021 (KR) 10-2021-0117587

(51) Int. Cl. H01L 23/00; H01L 23/15; H01L 23/538; H01L 25/065

(52) U.S. Cl. CPC H01L 24/29; H01L 23/5385; H01L 24/32; H01L 24/83; H01L 25/0655; H01L 23/15; H01L 24/33; H01L 2224/26122; H01L 2224/29139; H01L 2224/32245; H01L 2224/33181; H01L 2224/83007; H01L 2224/8302; H01L 2224/83801

(57) ABSTRACT

The present invention relates to a ceramic substrate for a power module, a method for manufacturing same, and a power module having same, the power module electrically connecting, by means of a conductive spacer, an electrode of a semiconductor device and a metal layer pattern of a ceramic substrate without a wire, thereby converting rated voltage and current while removing electrical risk factors, which may be generated during wire bonding, and increasing reliability and efficiency when used with high power.

### TECHNICAL FIELD

The present disclosure relates to a ceramic substrate for a power module, a method of manufacturing the same, and a power module including the ceramic substrate, and more particularly, to a ceramic substrate for a power module in which an electrode of a semiconductor device and a metal layer pattern of the ceramic substrate are electrically connected without a wire, a method of manufacturing the same, and a power module including the ceramic substrate.

### BACKGROUND ART

A power module is a semiconductor module that has been optimized for the conversion or control of power by modulating a semiconductor device into a package.

The power module has a structure in which a substrate is placed on a base plate and a semiconductor device is placed on the substrate.

In the existing power module, a semiconductor device is electrically connected to a substrate by wire bonding made of gold (Au), copper (Cu), or aluminum (Al). The existing power module has a structure in which the substrate is also connected to a PCB by wire bonding. That is, the existing power module has a structure in which a power movement line for an electrical signal and power conversion is formed of wire bonding.

However, the wire bonding structure becomes a potential danger factor for the entire vehicle because the wire bonding structure has the possibility that a short circuit or a disconnection may occur due to high power and high current electrical energy.

### DISCLOSURE

### Technical Problem

The present disclosure has been contrived to solve the aforementioned problem, and an object of the present disclosure is to provide a ceramic substrate for a power module, which can exclude a high-power and high-current electrical danger factor by electrically connecting an electrode of a semiconductor device and a metal layer pattern of the ceramic substrate without a wire through the medium of a conductive spacer, a method of manufacturing the same, and a power module including the ceramic substrate.

### Technical Solution

A ceramic substrate for a power module for achieving the aforementioned object according to an embodiment of the present disclosure is a ceramic substrate for a power module on which a plurality of semiconductor devices is mounted, and may include a ceramic base, a metal layer pattern formed on at least one surface of the ceramic base, a plurality of conductive spacers each having one surface bonded to the metal layer pattern, and a brazing filler layer configured to brazing-bond the metal layer pattern and the one surface of each of the conductive spacers. The conductive spacer may be disposed to be bonded to an electrode of the semiconductor device.

In this case, the metal layer pattern may include a first metal layer pattern formed on a top surface of the ceramic base and a second metal layer pattern formed on a bottom surface of the ceramic base. The conductive spacer may include a plurality of first conductive spacers each having one surface bonded to the first metal layer pattern and a plurality of second conductive spacers each having one surface bonded to the second metal layer pattern.

Meanwhile, the conductive spacer may be formed of at least one of Cu, Mo, a CuMo alloy, and a CuW alloy. The brazing filler layer may be made of a material comprising at least one of Ag, Cu, AgCu, and AgCuTi.

Meanwhile, the present disclosure may provide a power module including the aforementioned ceramic substrate for a power module. Specifically, the power module may include a pair of ceramic substrates in each of which a metal layer pattern has been formed on at least one surface of a ceramic base and a plurality of semiconductor devices disposed between the pair of ceramic substrates. Each of the pair of ceramic substrates may include a plurality of conductive spacers each having one surface bonded to the metal layer pattern and a brazing filler layer configured to brazing-bond the metal layer pattern and the one surface of each of the conductive spacers. The conductive spacer provided in at least one of the pair of ceramic substrates may be bonded to an electrode of the semiconductor device.

In this case, the metal layer pattern may include a first metal layer pattern formed on a top surface of the ceramic base and a second metal layer pattern formed on a bottom surface of the ceramic base. The conductive spacer may include a plurality of first conductive spacers each having one surface bonded to the first metal layer pattern and a plurality of second conductive spacers each having one surface bonded to the second metal layer pattern.

Furthermore, in each of the pair of ceramic substrates, any one of the first conductive spacer and the second conductive spacer may be bonded to the electrode of the semiconductor device.

Furthermore, in each of the pair of ceramic substrates, at least one of the first conductive spacer and the second conductive spacer may be formed to have an area corresponding to the electrode of the semiconductor device.

Furthermore, the number of first conductive spacers and the number of second conductive spacers may be identical with each other.

Meanwhile, the electrode of each of the semiconductor devices may be bonded to the other surface of each of the conductive spacers by a bonding layer including a solder or Ag paste.

Meanwhile, the present disclosure may provide a method of manufacturing a ceramic substrate for a power module on which a plurality of semiconductor devices is mounted. Specifically, the method may include forming a metal layer pattern on at least one surface of a ceramic base, preparing a plurality of conductive spacers, and brazing-bonding the metal layer pattern and one surface of each of the conductive spacers. The brazing-bonding may include disposing the conductive spacer so that the conductive spacer is bonded to an electrode of the semiconductor device.

In the preparing of the plurality of conductive spacers, the conductive spacer may be formed of at least one of Cu, Mo, a CuMo alloy, and a CuW alloy.

The brazing-bonding may further include disposing a brazing filler layer having a thickness of 5 μm or more to 100 μm or less between the one surface of each of the conductive spacers and the metal layer pattern by using any one method of paste coating, foil attachment, and a P-filler, and brazing the brazing filler layer by melting the brazing filler layer.

In the disposing of the brazing filler layer, the brazing filler layer may be made of a material including at least one of Ag, Cu, AgCu, and AgCuTi. Furthermore, the brazing may be performed at 450° C. or more.

### Advantageous Effects

According to the present disclosure, a rated voltage or current can be converted while removing an electrical danger factor which may occur upon wire bonding and improve reliability and efficiency can be improved when the present disclosure is used in high power, by electrically connecting the electrode of the semiconductor device and the metal layer pattern of the ceramic substrate without a wire through the medium of the conductive spacer.

Furthermore, according to the present disclosure, a height between the ceramic substrate and the semiconductor device can be easily adjusted in accordance with the height of a molding mold upon molding process because the conductive spacer is disposed between the metal layer pattern of the ceramic substrate and the electrode of the semiconductor device.

Furthermore, according to the present disclosure, heat dissipation efficiency can be improved because heat generated from the semiconductor device is easily transferred to the ceramic substrate through the conductive spacer.

Furthermore, according to the present disclosure, although a large number or a large quantity of semiconductor devices are integrated in order to reduce the size of the power module, a heat dissipation characteristic can be maximized because heat generated from the semiconductor device is dissipated from both sides of the semiconductor device through the conductive spacer provided in each of the pair of ceramic substrates.

Furthermore, according to the present disclosure, bonding strength is great and high temperature reliability is excellent because one surface of the conductive spacer is subjected to brazing bonding to the metal layer pattern of the ceramic substrate through the medium of the brazing filler layer and the other surface thereof is bonded to the electrode of the semiconductor device through the medium of the bonding layer including a solder or Ag paste.

### DESCRIPTION OF DRAWINGS

FIG. 1 is a perspective view illustrating a ceramic substrate for a power module according to an embodiment of the present disclosure.

FIG. 2 is a plan view illustrating the ceramic substrate for a power module according to an embodiment of the present disclosure.

FIG. 3 is a side view illustrating the ceramic substrate for a power module according to an embodiment of the present disclosure.

FIG. 4 is a side view illustrating the state in which a plurality of semiconductor devices has been bonded to the ceramic substrate for a power module in FIG. 3.

FIG. 5 is a side view illustrating an example in which a ceramic substrate for a power module according to an embodiment of the present disclosure has been disposed on both surfaces of the plurality of semiconductor devices.

FIG. 6 is a side view illustrating a ceramic substrate for a power module according to another embodiment of the present disclosure.

FIG. 7 is a bottom view illustrating the ceramic substrate for a power module according to another embodiment of the present disclosure.

FIG. 8 is a side view illustrating an example in which the ceramic substrate for a power module according to another embodiment of the present disclosure has been disposed on both surfaces of a plurality of semiconductor devices.

FIG. 9 is a flowchart illustrating a method of manufacturing a ceramic substrate for a power module according to an embodiment of the present disclosure.

### MODE FOR INVENTION

Hereinafter, embodiments of the present disclosure are described in detail with reference to the accompanying drawings. In the description of the embodiments, a criterion for a term “over/on” or “under/below” is described based on the drawings.

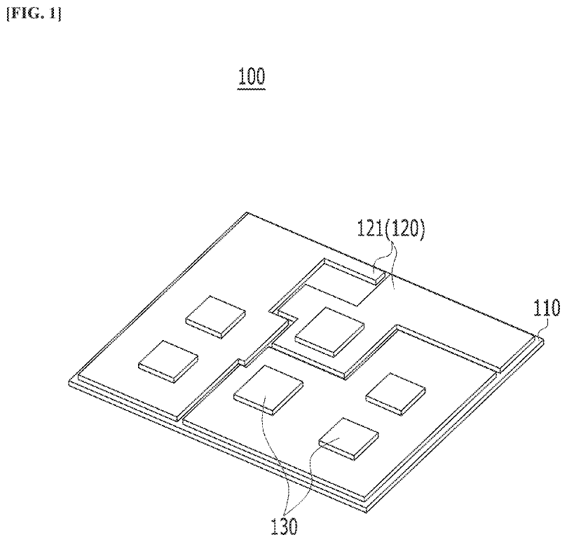

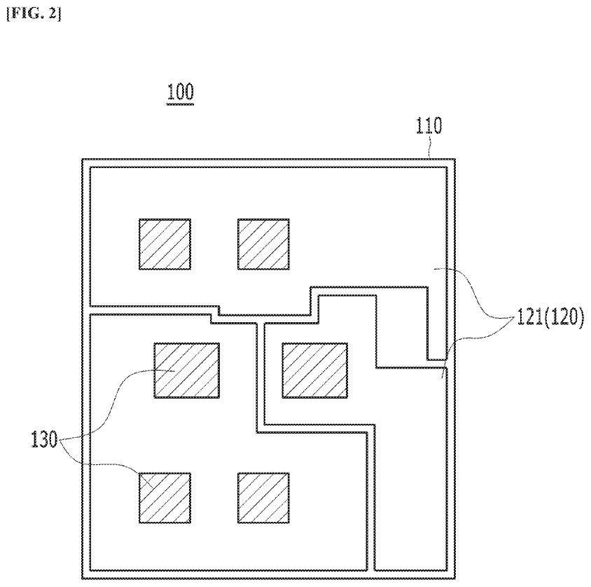

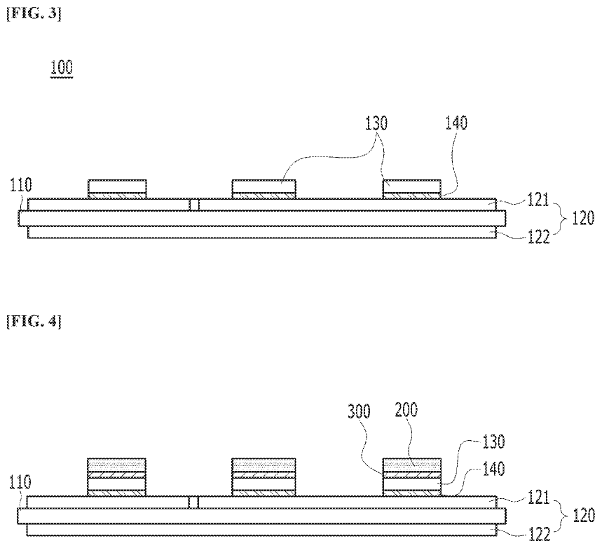

FIG. 1 is a perspective view illustrating a ceramic substrate for a power module according to an embodiment of the present disclosure. FIG. 2 is a plan view illustrating the ceramic substrate for a power module according to an embodiment of the present disclosure. FIG. 3 is a side view illustrating the ceramic substrate for a power module according to an embodiment of the present disclosure.

As illustrated in FIGS. 1 to 3, a ceramic substrate 100 for a power module according to an embodiment of the present disclosure may include a ceramic base 110, a metal layer pattern 120, a plurality of conductive spacers 130, and a brazing filler layer 140. A plurality of semiconductor devices 200 is mounted on the ceramic substrate 100 to constitute a power module. Unlike in a conventional power module using wire bonding, in the power module of the present disclosure, the electrodes of the plurality of semiconductor devices 200 are bonded to the plurality of conductive spacers 130 of the ceramic substrate 100. A high power and high current electrical danger factor can be excluded and heat dissipation performance can be improved because wire bonding is omitted.

The ceramic base 110 may be any one of alumina (Al₂O₃), AlN, SiN, and Si₃N₄, for example. The metal layer pattern 120 may be formed as an electrode pattern for mounting the semiconductor device or a surrounding part, which is formed as metal foil is subjected to brazing bonding to at least one surface of the ceramic base 110. For example, as illustrated in FIG. 3, the metal layer pattern 120 may include a first metal layer pattern 121 formed on a top surface of the ceramic base 110 and a second metal layer pattern 122 formed on a bottom surface of the ceramic base 110. The metal foil that forms the metal layer pattern 120 is aluminum foil or copper foil, for example. In this case, the metal foil is sintered on the ceramic base 110 at 780° C. to 1100° C. and subjected to brazing bonding to the ceramic base 110, for example. The substrate is called an active metal brazing (AMB) substrate. In the embodiment, the AMB substrate is described as an example, but a direct bonding copper (DBC) substrate or a thick printing copper (TPC) substrate may be applied. In this case, the AMB substrate is most suitable in terms of durability and heat dissipation efficiency.

Furthermore, in the ceramic substrate 100, the thickness of the ceramic base 110 may be 0.32 t and the thickness of each of the first metal layer pattern 121 and the second metal layer pattern 122 may be 0.3 t, for example, but the present disclosure is not limited thereto.

One surface of each of the plurality of conductive spacers 130 may be bonded to the metal layer pattern 120 of the ceramic substrate 100. The conductive spacer 130 may be provided in order to electrically connect the metal layer pattern 120 and the semiconductor device 200 and to adjust a height between the ceramic substrate 100 and the semiconductor device 200. The area of the conductive spacer 130 may be provided in the form of a block having a size of 0.5 mm or more and a thickness of 0.3 mm or more in accordance with the area of an electrode (not illustrated) of the semiconductor device 200. A form of the conductive spacer 130 is not limited thereto, and may be provided in various forms.

The ceramic substrate 100 for a power module may be sealed with molding resin (not illustrated), such as epoxy, in order to protect the ceramic substrate 100 against an external environment after the plurality of semiconductor devices 200 is mounted in accordance with the plurality of conductive spacers 130, respectively. The molding resin may be melted under a high temperature and high pressure and injected into a mold (not illustrated) in a liquefied form. The molding resin that has been hardened subsequently can protect the plurality of semiconductor devices 200 against an external environment, such as a physical impact, moisture, or pollution, and can stably maintain the coupling state of each component. It is necessary to adjust the height between the ceramic substrate 100 and the semiconductor device 200 depending on the height of the molding mold because the molding mold is used in the molding process as described above. If the height between the ceramic substrate 100 and the semiconductor device 200 is not properly adjusted depending on the height of the height of the molding mold, a problem in that the mold is filled with an epoxy molding compound (EMC) may occur. If pieces of equipment, such as the molding mold, are replaced depending on the height between the ceramic substrate 100 and the semiconductor device 200, it is not preferred because a lot of costs occur.

Accordingly, the ceramic substrate 100 for a power module according to an embodiment of the present disclosure may include the plurality of conductive spacers 130 that have been integrally bonded to the metal layer pattern 120. Each of the plurality of conductive spacers 130 may be disposed between the electrode of each of the plurality of semiconductor devices 200 and the metal layer pattern 120 of the ceramic substrate 100. As the conductive spacer 130 is formed to have a size corresponding to the height of the molding mold, the height between the ceramic substrate 100 and the semiconductor device 200 can be easily adjusted. For example, the height of the molding mold may be 3 mm to 4 mm. The conductive spacer 130 may be formed to have a thickness of 0.3 mm or more in accordance with the height of the molding mold.

If the height between the ceramic substrate 100 and the semiconductor device 200 is adjusted by forming the metal layer pattern 120 of the ceramic substrate 100 to be higher without disposing the conductive spacer 130, there is a disadvantage in that a lot of costs is required because the thickness of the entire metal layer pattern 120 needs to be further formed. In contrast, the present disclosure is much cheaper in terms of costs because the plurality of conductive spacers 130 for adjusting the height is disposed in portions to which the electrodes of the plurality of semiconductor devices 200 are bonded, respectively, in the metal layer pattern 120 of the ceramic substrate 100. Furthermore, productivity can be improved because the height between the ceramic substrate 100 and the semiconductor device 200 can be adjusted easily and variously depending on the height of the conductive spacer 130.

Furthermore, the conductive spacer 130 may be used to connect a circuit as a conductor. That is, in the state in which one surface of the conductive spacer 130 has been subjected to brazing bonding to the metal layer pattern 120 of the ceramic substrate 100, the electrode of the semiconductor device 200 may be bonded to the other surface of the conductive spacer 130. Accordingly, the conductive spacer 130 may electrically connect the electrode of the semiconductor device 200 to the metal layer pattern 120 of the ceramic substrate 100 without a wire.

As described above, according to the present disclosure, a rated voltage or current can be converted while removing an electrical danger factor which may occur upon wire bonding and reliability and efficiency can be improved when the present disclosure is used in high power, because wire bonding can be omitted by directly connecting the electrode of the semiconductor device 200 and the metal layer pattern 120 of the ceramic substrate 100 by using the conductive spacer 130.

The conductive spacer 130 may be made of at least one of Cu, Al, AlSiC, CuMo, CuW, Cu/Cu/MoCu, Cu/Mo/Cu, and Cu/W/Cu or a composite material of them. Preferably, the conductive spacer 130 may be made of at least one of Cu, Mo, a CuMo alloy, and a CuW alloy having an excellent coefficient of thermal expansion and excellent thermal conductivity.

For example, the conductive spacer 130 may be a 3-layer structure of Cu/CuMo/Cu. The 3-layer structure of Cu/CuMo/Cu is advantageous in heat dissipation because thermal conductivity is high, can stably maintain an interval between the ceramic substrate 100 and the semiconductor device 200 even at a high temperature because the 3-layer structure has a low coefficient of thermal expansion, and can minimize the occurrence of bending upon brazing bonding to the metal layer pattern 120 of the ceramic substrate 100.

The conductive spacer 130 may be provided in the state in which thermal stress, thermal deformation, etc. have been previously removed through thermal treatment. If thermal stress, thermal deformation, etc. are previously removed, bonding strength can be improved because thermal stress that occurs due to thermal expansion and thermal contraction in a process of the metal layer pattern 120 of the ceramic substrate 100 and the conductive spacer 130 being subjected to brazing bonding is reduced. Furthermore, a heat transfer effect may become excellent because a bonding portion is not damaged.

As illustrated in FIG. 3, one surface of each of the plurality of conductive spacers 130 may be brazing bonding to the metal layer pattern 120 through the medium of the brazing filler layer 140.

The brazing filler layer 140 brazing-bonds the metal layer pattern 120 and one surface of conductive spacer 130, and may be made of a material including at least one of Ag, Cu, AgCu, and AgCuTi. In this case, Ag and Cu each functions to increase bonding power due to high thermal conductivity and may each also improve heat dissipation efficiency by making heat transfer between the metal layer pattern 120 and the conductive spacer 130 easy. Furthermore, Ti may make Ag and Cu easily attached to the metal layer pattern 120 due to good wettability.

The brazing filler layer 140 may be formed as a thin layer having a multi-layer structure. The thin layer having the multi-layer structure is for increasing bonding power by supplementing insufficient performance. For example, the brazing filler layer 140 may be formed to have a 2-layer structure including an Ag layer and a Cu layer formed on the Ag layer. Alternatively, the brazing filler layer 140 may be formed to have a 3-layer structure including a Ti layer, an Ag layer formed on the Ti layer, and a Cu layer formed on the Ag layer. The boundary of the multi-layer structure of the brazing filler layer 140 may become ambiguous after the brazing filler layer is used in the brazing bonding of the metal layer pattern 120 and the conductive spacer 130. The brazing bonding may be performed at 450° C. or more.

FIG. 4 is a side view illustrating the state in which the plurality of semiconductor devices has been bonded to the ceramic substrate for a power module in FIG. 3.

As illustrated in FIG. 4, the other surface of each of the plurality of conductive spacers 130 may be bonded to the electrode of the semiconductor device 200 through the medium of the bonding layer 300. Although not illustrated, the conductive spacer 130 may be bonded to a gate electrode or source electrode of the semiconductor device 200. Accordingly, the conductive spacer may be electrically connected to the electrode of the semiconductor device 200.

The plurality of semiconductor devices 200 may each be at least one of an Si chip, an SiC chip, a GaN chip, a metal oxide semiconductor field effect transistor (MOSFET), an insulated gate bipolar transistor (IGBT), a junction field effect transistor (JFET), a high electric mobility transistor (HEMT), and a fast recovery diode (FRD).

For example, the electrode of the IGBT or SiC chip may be mounted on half of the plurality of conductive spacers 130. The FRD device is mounted on the remainder of the plurality of conductive spacers 130. Alternatively, the remaining half of the plurality of conductive spacers 130 may be used for heat dissipation or position fixing without including a separate device.

The bonding layer 300 is for bonding the electrode of the semiconductor device 200 and the other surface of the conductive spacer 130, and may include a solder or an Ag paste. When both one surface and the other surface of conductive spacer 130 are subjected to brazing bonding, bending may occur in the ceramic substrate 100 because two brazing processes need to be performed. Accordingly, it is preferred that the other surface of the conductive spacer 130 is bonded to the electrode of the semiconductor device 200 by the bonding layer 300 including a solder or Ag paste.

The solder may be formed of SnPb-based, SnAg-based, SnAgCu-based, or Cu-based solder paste having great bonding strength and excellent high-temperature reliability. The Ag paste has more excellent high temperature reliability and higher thermal conductivity than the solder. It is preferred that the Ag paste includes Ag powder of 90 to 99 weight % and a binder of 1 to10 weight % so that thermal conductivity is high. It is preferred that the Ag powder is nano particle. The Ag powder of the nano particle has high bonding density and high thermal conductivity due to a high surface area.

As described above, the ceramic substrate for a power module according to an embodiment of the present disclosure can improve productivity because the electrode of the semiconductor device 200 can be electrically connected to the metal layer pattern 120 without a wire through the conductive spacer 130 and the height between the ceramic substrate 100 and the semiconductor device 200 can be adjusted easily and variously in accordance with a molding mold. Furthermore, the ceramic substrate can have improved dissipation efficiency because heat that is generated from the semiconductor device 200 is transferred to the ceramic substrate 100 through the conductive spacer 130. Furthermore, the ceramic substrate has high bonding strength and excellent high-temperature reliability because one surface of the conductive spacer 130 is subjected to brazing bonding to the metal layer pattern 120 of the ceramic substrate 100 through the medium of the brazing filler layer 140 and the other surface thereof is bonded to the electrode of the semiconductor device 200 through the medium of the bonding layer 300.

FIG. 5 is a side view illustrating an example in which a ceramic substrate for a power module according to an embodiment of the present disclosure has been disposed on both surfaces of the plurality of semiconductor devices.

Referring to FIG. 5, the plurality of semiconductor devices 200 may be disposed between a pair of ceramic substrates 100A and 100B. The pair of ceramic substrates 100A and 100B may each include the plurality of conductive spacers 130 each having one surface bonded to the metal layer pattern 120 and the brazing filler layer 140 that brazing-bonds the metal layer pattern 120 and the one surface of each of the conductive spacers 130. The conductive spacer 130 of at least one of the pair of ceramic substrates 100A and 100B may be electrically connected to the electrode of the semiconductor device 200 by being bonded to the electrode of the semiconductor device. For example, an electrode formed on a top surface of the semiconductor device 200 may be electrically connected to the conductive spacer 130 provided in the upper ceramic substrate 100A by being bonded to the conductive spacer through the medium of the bonding layer 300. An electrode formed on a bottom surface of the semiconductor device 200 may be electrically connected to the conductive spacer 130 provided in the lower ceramic substrate 100B by being bonded to the conductive spacer through the medium of the bonding layer 300. Alternatively, the electrode of the semiconductor device 200 may be formed only on the bottom surface, and may be bonded to the conductive spacer 130 of the lower ceramic substrate 100B. The top surface of the semiconductor device 200 may be bonded to the conductive spacer 130 of the upper ceramic substrate 100A for heat dissipation. If a double-sided cooling type structure in which the pair of ceramic substrates 100A and 100B has been disposed on both surfaces of the plurality of semiconductor devices 200 as described above is applied, heat dissipation performance can be further improved.

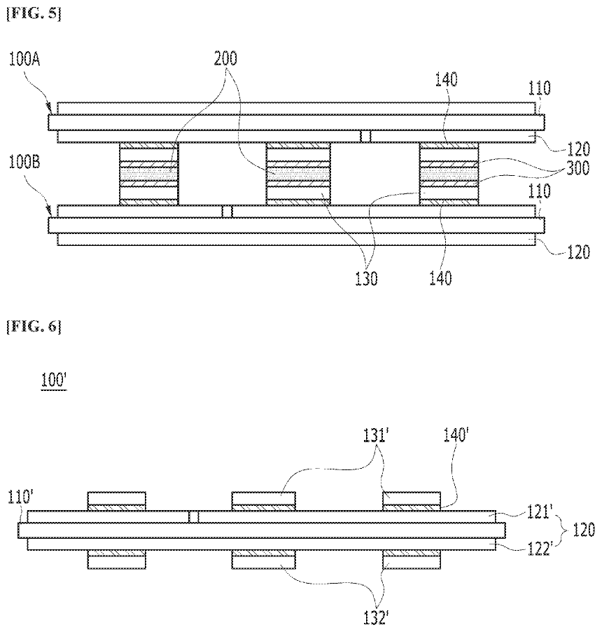

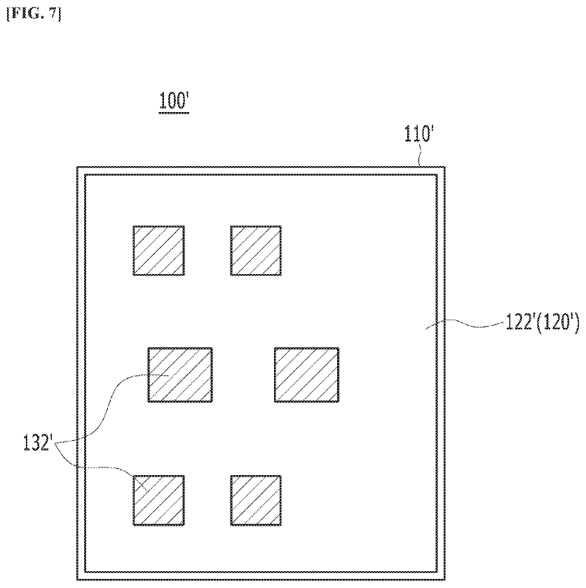

Hereinafter, a ceramic substrate for a power module according to another embodiment of the present disclosure is described with reference to FIGS. 6 to 8.

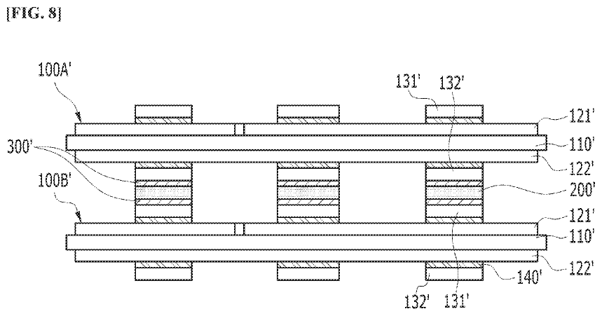

FIG. 6 is a side view illustrating a ceramic substrate for a power module according to another embodiment of the present disclosure. FIG. 7 is a bottom view illustrating the ceramic substrate for a power module according to another embodiment of the present disclosure. FIG. 8 is a side view illustrating an example in which the ceramic substrate for a power module according to another embodiment of the present disclosure has been disposed on both surfaces of a plurality of semiconductor devices.

Referring to FIGS. 6 and 7, a ceramic substrate 100′ for a power module may include a first metal layer pattern 121′ formed on a top surface of a ceramic base 110′ and a second metal layer pattern 122′ formed on a bottom surface of the ceramic base 110′. Furthermore, the ceramic substrate 100′ may include a plurality of first conductive spacers 131′ each having one surface bonded to the first metal layer pattern 121′ and a plurality of second conductive spacers 132′ each having one surface bonded to the second metal layer pattern 122′. One surface of the first conductive spacer 131′ may be subjected to brazing bonding to the first metal layer pattern 121′ through the medium of a brazing filler layer 140′. One surface of the second conductive spacer 132′ may be subjected to brazing bonding to the second metal layer pattern 122′ through the medium of the brazing filler layer 140′.

In an upper ceramic substrate 100A′ and a lower ceramic substrate 100B′, the number of first conductive spacers 131′ and the number of second conductive spacers 132′ may be the same. An arrangement form of each of the first conductive spacers 131′ and the second conductive spacers 132′ is not limited to the forms illustrated in the drawings. For example, the first conductive spacers 131′ and the second conductive spacers 132′ may be disposed at positions at which they have been dislocated with respect to each other or at positions at which they face each other on the basis of the ceramic base 110′ depending on their use.

In the ceramic substrate 100′ for a power module according to another embodiment of the present disclosure, the conductive spacers 131′ and 132′ are provided on both surfaces of the ceramic substrate 100′ compared to the embodiment illustrated in FIGS. 1 to 5. If a great quantity of power semiconductor devices is integrated in order to reduce the size of a power module, a large amount of heat is generated. Accordingly, a heat dissipation characteristic can be maximized by applying a double-sided heat dissipation structure through the conductive spacers 131′ and 132′ provided on both surfaces of the ceramic substrate 100′ of the present disclosure. The conductive spacers 131′ and 132′ can effectively dissipate heat generated from the semiconductor device 200 because the conductive spacer may be made of at least one of Cu, Mo, a CuMo alloy, and a CuW alloy having an excellent coefficient of thermal expansion and excellent thermal conductivity.

Referring to FIG. 8, a plurality of semiconductor devices 200′ may be disposed between the upper ceramic substrate 100A′ and the lower ceramic substrate 100B′. The upper ceramic substrate 100A′ and the lower ceramic substrate 100B′ may include the plurality of first conductive spacers 131′ each having one surface bonded to the first metal layer pattern 121′ and the plurality of second conductive spacers 132′ each having one surface bonded to the second metal layer pattern 122′. In this case, any one of the first conductive spacer 131′ and the second conductive spacer 132′ may be bonded and electrically connected to the electrode of the semiconductor device 200. Furthermore, at least one of the first conductive spacer 131′ and the second conductive spacer 132′ may be formed to have an area corresponding to the electrode of the semiconductor device 200′.

Each of the plurality of semiconductor devices 200′ may be disposed between the second conductive spacer 132′ of the upper ceramic substrate 100A′ and the first conductive spacer 131′ of the lower ceramic substrate 100B′. For example, an electrode formed on a top surface of the semiconductor device 200′may be bonded and electrically connected to the second conductive spacer 132′ provided in the upper ceramic substrate 100A′ through the medium of the bonding layer 300′. An electrode formed on a bottom surface of the semiconductor device 200′ may be bonded and electrically connected to the first conductive spacer 131′ of the lower ceramic substrate 100B′ through the medium of the bonding layer 300′. Alternatively, the electrode of the semiconductor device 200′ may be formed only on the bottom surface and bonded to the first conductive spacer 131′ of the lower ceramic substrate 100B′. In this case, the top surface of the semiconductor device 200′ may be bonded to the second conductive spacer 132′ of the upper ceramic substrate 100A′ for heat dissipation. If a double-sided cooling type structure in which the pair of ceramic substrates 100A′ and 100B′ has been disposed on both surfaces of the plurality of semiconductor devices 200′ as described above is applied, heat dissipation performance can be further improved.

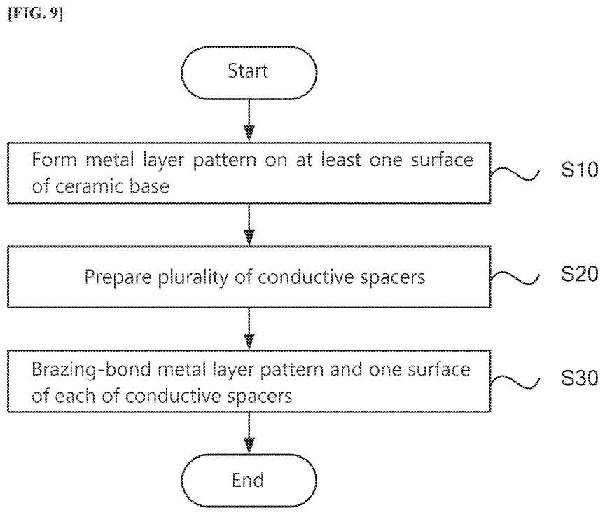

FIG. 9 is a flowchart illustrating a method of manufacturing a ceramic substrate for a power module according to an embodiment of the present disclosure.

As illustrated in FIG. 9, the method of manufacturing the ceramic substrate for a power module on which the plurality of semiconductor devices 200 is mounted may include step S10 of forming the metal layer pattern 120 on at least one surface of the ceramic base 110, step S20 of preparing the plurality of conductive spacers 130, and step S30 of brazing-bonding the metal layer pattern 120 and one surface of each of the conductive spacers 130.

In step S10 of forming the metal layer pattern 120 on at least one surface of the ceramic base 110, the ceramic base 110 may be any one of alumina (Al₂O₃), AlN, SiN, and Si₃N₄. Furthermore, the metal layer pattern 120 may be formed as an electrode pattern for mounting a semiconductor device or a surrounding part, which is formed as aluminum foil or copper foil is subjected to brazing bonding to at least one surface of the ceramic base 110.

In step S20 of preparing the plurality of conductive spacers 130, the conductive spacer 130 may be made of at least one of Cu, Mo, a CuMo alloy, and a CuW alloy. For example, the area of the conductive spacer 130 may be provided in the form of a block having a size of 0.5 mm or more and a thickness of 0.3 mm or more in accordance with the area of an electrode (not illustrated) of the semiconductor device 200.

Step S30 of brazing-bonding one surface of each of the metal layer pattern 120 and the conductive spacer 130 may include a step of disposing the conductive spacer 130 so that the conductive spacer is bonded to the electrode of the semiconductor device 200. As described above, the conductive spacer 130 may be integrally provided in the ceramic substrate 100 and disposed between the electrode of the semiconductor device 200 and the metal layer pattern 120 of the ceramic substrate 100 upon mounting of the semiconductor device 200. Accordingly, there are advantages in that the conductive spacer 130 can be easily used to adjust a height between the ceramic substrate 100 and the semiconductor device 200, a heat dissipation characteristic can be maximized, and the electrode of the semiconductor device 200 can be electrically connected to the metal layer pattern 120 without a wire.

Step S30 of performing the brazing bonding may further include a step of disposing the brazing filler layer 140 having a thickness of 5 μm or more to 100 μm or less between one surface of each of the conductive spacers 130 and the metal layer pattern 120 by using any one method of paste coating, foil attachment, and a P-filler, and a step of brazing the brazing filler layer 140 by melting the brazing filler layer.

In the step of disposing the brazing filler layer 140, the brazing filler layer 140 may be made of a material including at least one of Ag, Cu, AgCu, and AgCuTi.

The step of brazing the brazing filler layer 140 by melting the brazing filler layer may be performed at 450° C. or more. Upper weighting or pressurization may be performed in order to increase bonding power and so that void is not generated during the brazing.

As described above, according to the present disclosure, productivity can be improved because the electrode of the semiconductor device 200 can be electrically connected to the metal layer pattern 120 of the ceramic substrate 100 through the conductive spacer 130 without a wire and the height between the ceramic substrate 100 and the semiconductor device 200 can be adjusted easily and variously in accordance with a molding mold. Furthermore, heat dissipation efficiency can be improved because heat generated from the semiconductor device 200 is transferred to the ceramic substrate 100 through the conductive spacer 130. Furthermore, bonding strength is high and high temperature reliability is excellent because the conductive spacer 130 has one surface subjected to brazing bonding to the metal layer pattern 120 through the medium of the brazing filler layer 140 and has the other surface bonded to the electrode of the semiconductor device 200 through the medium of the bonding layer 300.

Although the present disclosure has been described with reference to the exemplary drawings, it is evident to a person having ordinary knowledge in the art that the present disclosure is not limited to the described embodiments and may be variously changed and modified without departing from the spirit and range of the present disclosure. Accordingly, such changed examples or modified examples should be considered to belong to the claims of the present disclosure, and the scope of rights of the present disclosure should be interpreted based on the claims.

1. A ceramic substrate for a power module on which a plurality of semiconductor devices is mounted, the ceramic substrate comprising:
a ceramic base;
a metal layer pattern formed on at least one surface of the ceramic base;
a plurality of conductive spacers each having one surface bonded to the metal layer pattern; and
a brazing filler layer configured to brazing-bond the metal layer pattern and the one surface of each of the conductive spacers,
wherein the conductive spacer is disposed to be bonded to an electrode of the semiconductor device.

2. The ceramic substrate of claim 1, wherein:
the metal layer pattern comprises a first metal layer pattern formed on a top surface of the ceramic base and a second metal layer pattern formed on a bottom surface of the ceramic base, and
the conductive spacer comprises a plurality of first conductive spacers each having one surface bonded to the first metal layer pattern and a plurality of second conductive spacers each having one surface bonded to the second metal layer pattern.

3. The ceramic substrate of claim 1, wherein the conductive spacer is formed of at least one of Cu, Mo, a CuMo alloy, and a CuW alloy.

4. The ceramic substrate of claim 1, wherein the brazing filler layer is made of a material comprising at least one of Ag, Cu, AgCu, and AgCuTi.

5. A power module comprising:
a pair of ceramic substrates in each of which a metal layer pattern has been formed on at least one surface of a ceramic base; and
a plurality of semiconductor devices disposed between the pair of ceramic substrates,
wherein each of the pair of ceramic substrates comprises:
a plurality of conductive spacers each having one surface bonded to the metal layer pattern; and
a brazing filler layer configured to brazing-bond the metal layer pattern and the one surface of each of the conductive spacers, and
wherein the conductive spacer provided in at least one of the pair of ceramic substrates is bonded to an electrode of the semiconductor device.

6. The power module of claim 5, wherein:
the metal layer pattern comprises a first metal layer pattern formed on a top surface of the ceramic base and a second metal layer pattern formed on a bottom surface of the ceramic base, and
the conductive spacer comprises a plurality of first conductive spacers each having one surface bonded to the first metal layer pattern and a plurality of second conductive spacers each having one surface bonded to the second metal layer pattern.

7. The power module of claim 6, wherein in each of the pair of ceramic substrates, any one of the first conductive spacer and the second conductive spacer is bonded to the electrode of the semiconductor device.

8. The power module of claim 6, wherein in each of the pair of ceramic substrates, at least one of the first conductive spacer and the second conductive spacer is formed to have an area corresponding to the electrode of the semiconductor device.

9. The power module of claim 6, wherein a number of first conductive spacers and a number of second conductive spacers are identical with each other.

10. The power module of claim 5, wherein the electrode of each of the semiconductor devices is bonded to the other surface of each of the conductive spacers by a bonding layer comprising a solder or Ag paste.

11. A method of manufacturing a ceramic substrate for a power module on which a plurality of semiconductor devices is mounted, the method comprising:
forming a metal layer pattern on at least one surface of a ceramic base;
preparing a plurality of conductive spacers; and
brazing-bonding the metal layer pattern and one surface of each of the conductive spacers,
wherein the brazing-bonding comprises disposing the conductive spacer so that the conductive spacer is bonded to an electrode of the semiconductor device.

12. The method of claim 11, wherein in the preparing of the plurality of conductive spacers, the conductive spacer is formed of at least one of Cu, Mo, a CuMo alloy, and a CuW alloy.

13. The method of claim 11, wherein the brazing-bonding further comprises:
disposing a brazing filler layer having a thickness of 5 μm or more to 100 μm or less between the one surface of each of the conductive spacers and the metal layer pattern by using any one method of paste coating, foil attachment, and a P-filler, and
brazing the brazing filler layer by melting the brazing filler layer.

14. The method of claim 13, wherein in the disposing of the brazing filler layer, the brazing filler layer is made of a material comprising at least one of Ag, Cu, AgCu, and AgCuTi.

15. The method of claim 13, wherein the brazing is performed at450° C. or more.
